(19) United States
(12) Patent Application Publication
(10) Pub. No.: US 2009/0274177 A1
(43) Pub. Date: Nov. 5, 2009

(54) TURNABLE LASER DEVICE

(75) Inventors: Li Fan, Tucson, AZ (US); Mahmoud Fallahi, Tucson, AZ (US); Jerome V. Moloney, Tucson, AZ (US)

Correspondence Address: OBLON, SPIVAK, MCCLELLAND MAIER & NEUSTADT, L.L.P., 1940 DUKE STREET, ALEXANDRIA, VA, 22314, US

(73) Assignee: The Arizona BD of Reg on Behalf of The Univ of AZ, Tucson, AZ (US)

(21) Appl. No.: 12/159,794

(22) PCT Filed: Jan. 4, 2007
(86) PCT No.: PCT/US07/00043

§ 371 Date: Oct. 10, 2008

Related U.S. Application Data
(60) Provisional application No. 60/756,128, filed on Jan. 4, 2006.

(51) Int. Cl. H01S 3/10; H01S 3/08; H01S 5/00

(52) U.S. Cl. 372/20; 372/99; 372/45.011; 372/22

(57) ABSTRACT

A laser apparatus includes a first surface-emitting laser device having an active region including at least one group of two or more quantum wells configured to generate photons and having an internal mirror configured to reflect the generated photons, and first and second opposing end cavity mirrors optically coupled to each other via the internal mirror of the first surface-emitting laser device and arranged to reflect the photons generated by the first surface-emitting laser device back to the first surface-emitting laser device to form a standing wave having a single antinode coincident with said at least one group of two or more quantum wells.

### CROSS-REFERENCE TO RELATED APPLICATIONS

This application claims benefit of priority under 35 U.S.C. §119 to U.S. provisional application 60/756,128 filed on Jan. 4, 2006, the entire contents of which are incorporated herein by reference.

### STATEMENT REGARDING FEDERALLY SPONSORED RESEARCH OR DEVELOPMENT

The U.S. Government has a paid-up license in this invention and the right in limited circumstances to require the patent owner to license others on reasonable terms as provided for by the terms of F49620-02-1-0380, awarded by the Air Force Office of Scientific Research.

### DISCUSSION OF THE BACKGROUND

1. Field of the Invention

This application is related to wavelength tuning and wavelength locking of an output of a laser structure. More specifically, this patent application is related to a tunable laser structure that includes a vertical-external-cavity surface-emitting laser and the laser structure is capable of wavelength tuning the output laser beam.

2. Discussion of the Background

Optically pumped semiconductor vertical-external-cavity surface-emitting lasers (VECSELs) have shown their potential in a range of commercial and defense applications for their high power and good beam quality. However, thermally induced wavelength shift and wide linewidth are drawbacks for applications where laser wavelength stability is required.

Tunable electrically or optically pumped vertical-external cavity lasers (VCSELs) based on microelectromechanical systems (MEMS) use a movable mirror technique to achieve a mode-hop-free wavelength tuning with a wide tuning range. However, these arrangements are typically low power (milliwatt level), and their sophisticated MEMS structures make their fabrication difficult.

Although the VECSEL lasers are attractive for high-power and high-brightness operation, they are typically composed of multiple quantum wells in which a single quantum well is placed at an antinode of a cavity standing wave to achieve a maximum relative confinement factor (Γᵣ=2). The positions of the antinodes of the cavity standing wave are then controlled by the optical thickness of the microcavity. Growth variation, process control, and the thermally induced refractive index changes can change the optical thickness of the microcavity, resulting in a mismatch between the antinodes and the quantum wells. These events affect the high-power high-temperature operation of the conventional VECSELs.

### SUMMARY OF THE INVENTION

According to one aspect of the present invention, a laser device includes a first surface-emitting laser device having an active region including at least one group of two or more quantum wells configured to generate photons and having an internal mirror configured to reflect the generated photons, and first and second opposing end cavity mirrors optically coupled to each other via the internal mirror of the first surface-emitting laser device and arranged to reflect the photons generated by the first surface-emitting laser device back to the first surface-emitting laser device to form a standing wave having a single antinode coincident with said at least one group of two or more quantum wells.

According to another aspect of the present invention, a method for tuning a laser beam includes emitting from a first surface-emitting laser device having an active region that includes at least one group of two or more quantum wells an electromagnetic wave in a first optical path towards a first end cavity mirror, reflecting the emitted electromagnetic wave from the first end cavity mirror back to an internal mirror of the first surface-emitting laser device for amplification by the first surface-emitting laser device and further emission of the amplified electromagnetic wave in a second optical path to a second end cavity mirror opposing the first end cavity mirror via the first and second optical paths, and reflecting the amplified electromagnetic wave from the second end cavity mirror back to the first surface-emitting device for further amplification of the electromagnetic wave so that a standing wave having a single antinode located at the at least one group of two or more quantum wells in the active region is formed.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein

FIG. 1 is a schematic diagram of a tunable VECSEL structure with a V-shaped cavity;

FIG. 2 shows the structure of the VECSEL chip having double-wells;

FIG. 3 shows another structure of the VECSEL chip;

FIG. 4 shows the structure of a VECSEL chip having a single-well;

FIG. 5 is a schematic diagram of a laser beam reflected on the VECSEL chip;

FIG. 6 is a graph showing an output power versus a net pump power for a VECSEL chip;

FIG. 7 is a graph showing a comparison of lasing spectra with/without the birefringent filter in the V-shaped cavity;

FIG. 8 is a graph showing a tuning range of the VECSEL structure of FIG. 1;

FIG. 9 is a graph showing the lasing spectra of the VECSEL structure of FIG. 1;

FIG. 10 is a schematic diagram of a tunable two-chip VECSEL structure with a W-shaped cavity and a birefringent filter;

FIGS. 11a-c are graphs showing the tunable output power versus the tuning wavelength for a single chip and two-chips VECSEL structures;

FIG. 12 is a graph showing the tuning spectra of the VECSEL structure of FIG. 10;

FIG. 13 is a schematic diagram of a tunable blue-green VECSEL structure with a Z-shaped cavity and a birefringent filter;

FIG. 14 is a graph showing a total blue-green continuous wave power of the VECSEL structure of FIG. 13;

FIGS. 15a-c are graphs showing spectra of 488 nm intracavity and a 976 fundamental signal;

FIG. 16 is a graph showing an output of the blue-green polarized VECSEL; and

FIG. 17 is a graph showing several spectra of the intracavity;

### DESCRIPTION OF THE EMBODIMENTS

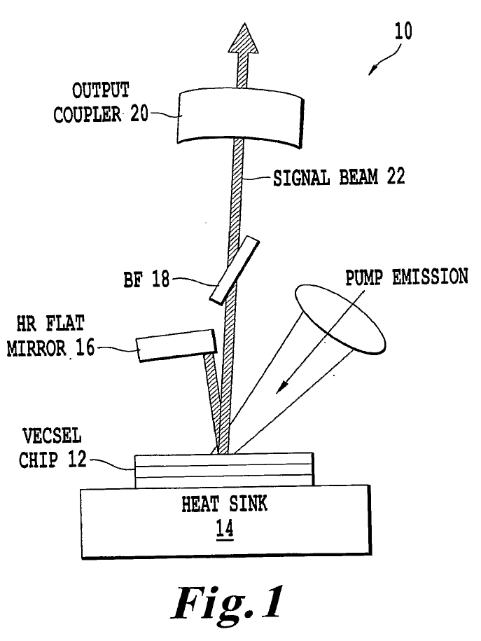

Referring now to the drawings, wherein like reference numerals designate identical or corresponding parts throughout the several views, and more particularly to FIG. 1 thereof, FIG. 1 shows a tunable high-power (multiwatt), high-brightness linearly polarized VECSEL structure 10 having a 30 nm tuning range and a narrow linewidth.

The VECSEL structure 10 shown in FIG. 1 emits a laser beam around 975 nm. However, the tuning range discussed herein is applicable to a VECSEL structure having a laser beam with any wavelength. The 975 nm wavelength for the VECSEL structure 10 shown in FIG. 1 is for illustrative purposes and not intended to limit the present invention.

The VECSEL structure 10 includes a VECSEL chip 12 that optionally is provided on a temperature control unit 14. The temperature control unit 14 may include a heat sink to maintain constant a temperature of the VECSEL chip 12. The temperature control unit 14 may also include a fan, a thermoelectric cooler (TEC), copper water cooler, a microchannel cooler or other known devices for maintaining constant the temperature. In addition, the VECSEL structure 10 may include a flat mirror 16, which has preferably a high reflectivity, a birefringent filter BF 18, and an output coupler mirror 20. Some of the photons generated and amplified by the VECSEL chip 12 are reflected by the flat mirror 16 back to the VECSEL chip 12 and then outputted as the laser beam 22 by the output coupler mirror 20 after the laser beam 22 has passed the BF 18. In this way, the laser beam 22 has passed the VECSEL chip 12 four times in a round trip with advantages that will be discussed next.

The VECSEL chip 12 may be grown by conventional methods known by one of ordinary skill in the art, for example metalorganic vapor phase epitaxy on undoped GaAs substrate. An active region of the VECSEL chip 12 may include multiple single quantum wells, groups of double quantum wells, or any other group that includes a quantum well combination.

However, the VECSEL chip 12 is configured such that a cavity standing wave determined by the microcavity of the VECSEL chip 12 has a single antinode coincident with at least one group of multiple quantum wells. It is noted that by having groups of two or more quantum wells with at least one group coinciding with a single antinode of the standing wave an more powerfull laser beam is achieved relative to the conventional surface-emitting lasers that have each single quantum well coincident with a single antinode of the standing wave.

For example, according to an embodiment, a group of quantum wells has two quantum wells and thus, the single antinode of the standing wave coincide with a strain compensating layer formed between the two quantum wells. If the group includes three quantum wells according to another embodiment, the single antinode would coincide with the middle quantum well.

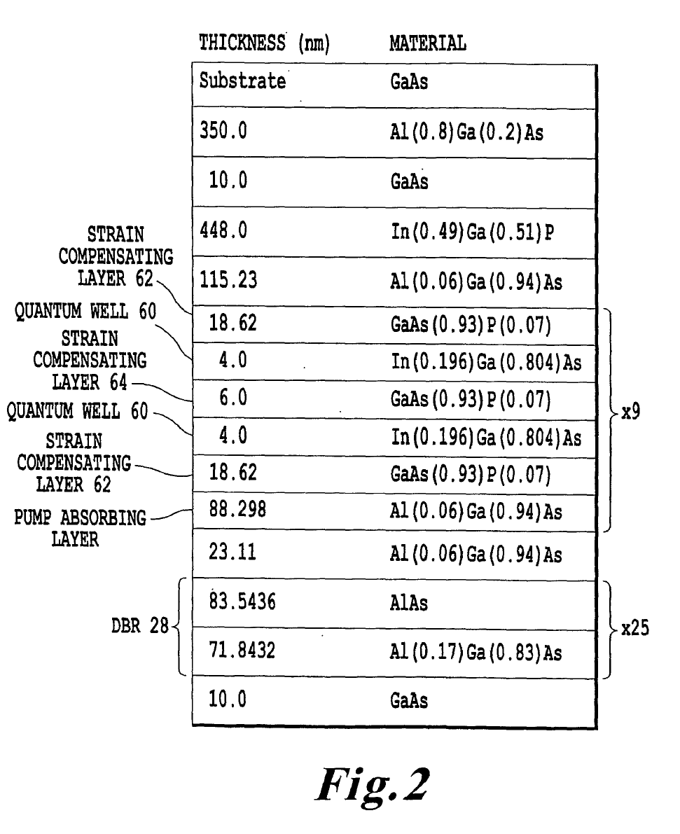

The active region of the VECSEL chip 12 shown in FIG. 2 includes nine groups of double quantum wells, each group including two 4 nm compressive strained InGaAs quantum wells separated by a 6 nm thick GaAsP strain compensating layer. The quantum wells may include an InₓGa₁₋ₓAs layer with 0.0<x<1.0, and x can be selected such that a wavelength generated by the quantum wells is between 900 and 1200 nm. The number of the groups of double quantum wells is preferably between 7 and 18. However, other number of groups of double or multiple wells is possible. FIG. 2 shows a substrate 20 of GaAs on which the quantum wells 22 are formed with the strain compensating layers 24 interposed. The structure of the quantum well 22, the strain compensating layer 24 and the pump absorbing layer 26 is repeated 9 times and the structure of the DBR 28 is repeated 25 times.

The quantum wells 60 shown in FIG. 2 may have a thickness between 2 and 12 nm and the external strain compensating layers 62 may have a thickness less than 50 nm, preferable around 20 μm. The internal strain compensating layer 64 may have a thickness between 2 and 12 nm. The thickness of the other layers that form the VECSEL chip are shown in FIG. 2 and are for exemplary purposes. However, it is understood that thickness of the layers to be used in the VECSEL chip may vary from the values shown in FIG. 2.

In an exemplary embodiment, adjacent double wells 22 are separated by two 18.6 nm wide GaAsP strain compensating layers 24 and an 88.3 nm thick AlGaAs barrier 26 in which the pump light is absorbed. The thickness and compositions of the layers (shown in FIG. 2) are such that each double well 22 is positioned at an antinode of the cavity standing wave to provide resonant periodic gain (RPG) in the active region of the VECSEL chip 12.

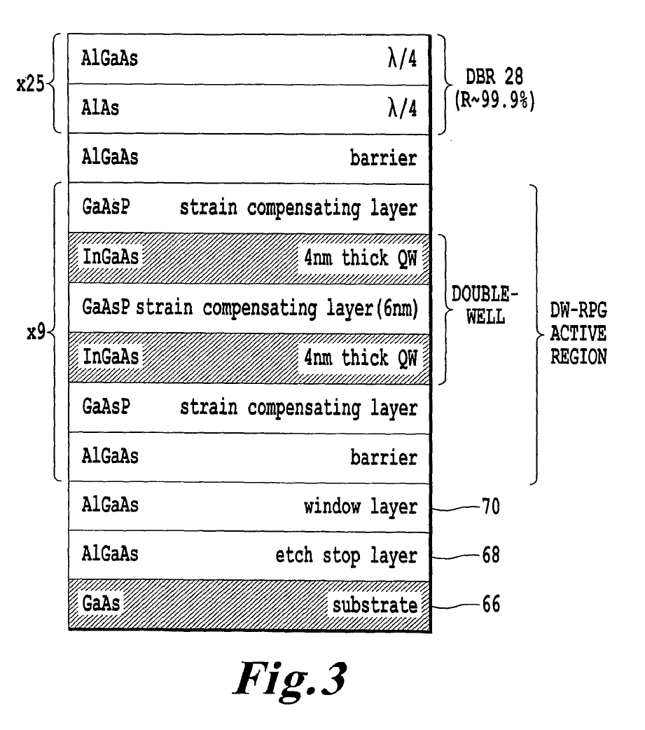

This double-well resonant periodic gain structure overcomes a mismatch between the antinodes and the quantum nodes in the conventional VECSEL structures. The “double-well” resonant periodic gain structure (DW-RPG) shown in FIG. 3 has two thin quantum wells placed at each antinode. The resulting DW-RPG structure is robust for high-power and high-temperature operation.

FIG. 3 shows the VECSEL chip 12 built to emit near 975 nun. The active region includes nine double-wells each comprised of two 4-nm compressive strained InGaAs quantum wells separated by a 6-nm-thick GaAsP strain compensating layer. The thickness and compositions of the layers are such that each antinode of the standing wave is positioned at the middle of 6-nm-thick GaAsP strain compensating layer, providing a strong confinement factor. Also, the barrier materials are chosen to give good carrier confinement in the wells, and thus, a high gain, while keeping the excess energy of the pumped carriers to a minimum in order to limit heating. The number of wells is found by balancing between large gain and limited threshold powers. A high reflectivity (R>99.9%) distributed Bragg reflector (DBR) stack made of 25 pairs of AlGaAs-AlAs is grown on the top of the active region.

It is noted with regard to FIG. 3 that a substrate 66 and an etch stop layer 68 are used during the formation of the VECSEL chip but these two layers are removed when the VECSEL chip is used. A window layer 70 and the DBR 28 define the microcavity 30 of the VECSEL chip 12.

Compared to a VECSEL chip using an 8-nm-thick single-well RPG (SW-RPG) structure, this DW-RPG structure has several advantages. For a given carrier density and temperature, the material gain for a 4-nm-thick quantum well significantly exceeds twice the value obtained for an 8-nm-thick quantum well. Also, the thinner well results in a larger density of states for each subband and larger subband separation, thus higher percentage of carriers occupies the lowest subband, leading to a large inversion (1−fₑ−fₕ) and higher gain. Thus, the modal gain for a double-well with 4-nm-wide wells is larger than for a single-well with an 8-nm-wide well. Since the gain material of a double-well is spread out over a larger region (14 nm total), the geometry increases the tolerance to the growth variation and process control. This geometry can also compensate for any temperature gradient between various wells and the temperature control unit, and thermally induced shift of the antinodes of the lasing modes.

Furthermore, the DW-RPG configuration can support more quantum wells while maintaining a thinner active region, which can achieve more efficient heat dissipation. In one embodiment of the invention, the DW-RPG configuration includes two or more pairs of quantum wells. A structure including between 7 and 18 pairs of quantum wells may be used.

In addition to the RPG active region and DBR stack, optionally there is a high aluminum concentration AlGaAs etch-stop layer between the active region and the substrate to facilitate selective chemical substrate removal, as shown in FIG. 2. The epitaxial side of the VECSEL wafer is mounted on chemical vapor deposition (CVD) diamond by indium solder. After the removal of the GaAs substrate and the etch-stop layer, a single-layer Si₃N₄ (n=1.78) quarter-wave low-reflectivity coating is deposited on the surface of VECSEL chip to achieve a reflectivity less than 1% at the signal wavelength.

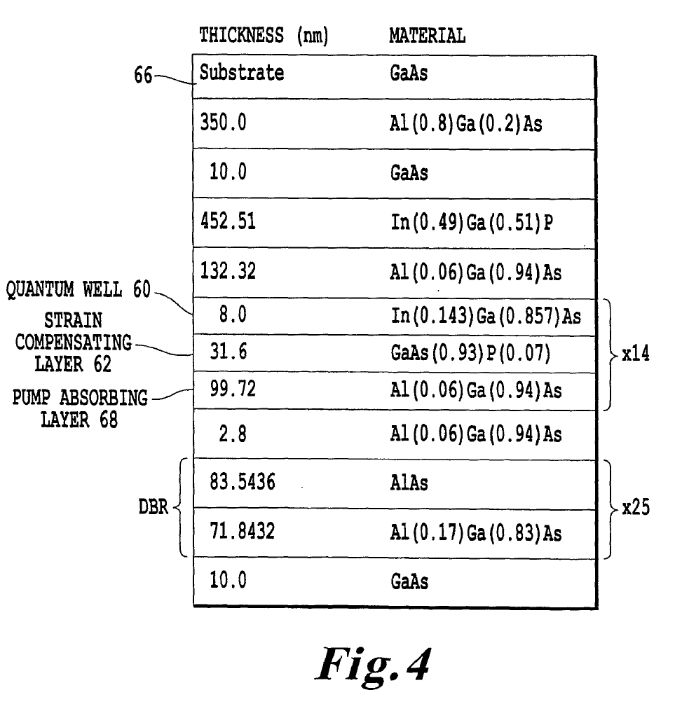

According to another embodiment, FIG. 4 shows the 8-nm-thick single-well RPG SW-RPG structure discussed above. This structure shows only a single quantum well 22 formed on the substrate 66 and a strain compensating layer 62 formed between the quantum well 60 and the pump absorbing layer 68. The structure of the quantum well 60, the strain compensating layer 62 and the pump absorbing layer 68 is repeated 14 times and the structure of the DBR 28 is repeated 25 times. Both the SW-RPG and the DW-RPG as well as any other combination of multiple wells achieve a tunable output as will be discussed later.

To achieve the tunable high-power VECSEL structure with a wide tuning range, in one embodiment of the present invention a V-shaped cavity is used in conjunction with the birefringent filter BF 18 shown in FIG. 1. However, other wavelength tuning components may be used instead of the birefringent filter 18. In this respect, it is noted that the birefringent filter 18 is used in this embodiment for illustrative purposes. Other wavelength tuning components that achieve a similar function as the birefringent filter are for example electro-optical components such as Pockels and Kerr effects-based components, a Fabry-Perot etalon, or liquid crystals components.

The V-shaped cavity has a first end defined by the flat mirror 16 and the other end by the output coupler mirror 20. However, another cavity may be used as long as at least one VECSEL chip is provided at a folding position of the cavity. In the V-shaped cavity, the VECSEL chip 12 is placed at the fold of the V-shaped cavity. The flat mirror 16 and the output coupler mirror 20 each have preferably a high-reflectivity (R>99.9%).

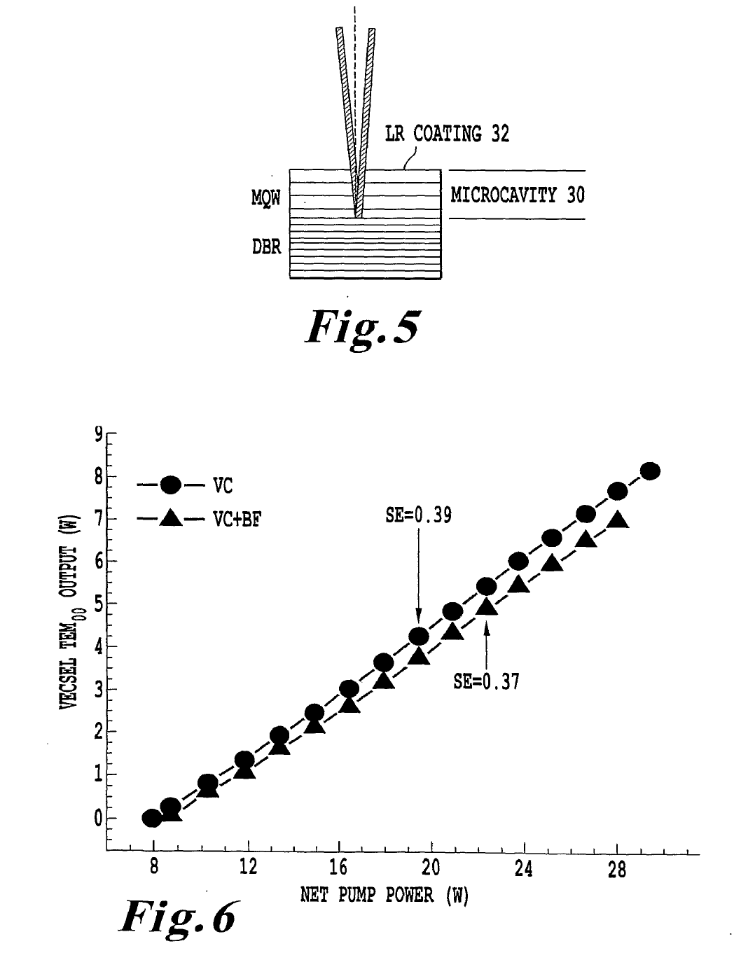

Since a signal beam 22 of the V-shaped cavity is incident to the VECSEL chip 12 with a small incident angle as shown in FIG. 5, the propagation direction of the signal beam 22 in the semiconductor microcavity 30, formed by the DBR 28 and the semiconductor/air interface, is not perpendicular to the surface of the VECSEL chip 12 and the DBR mirror. As a result, the cavity eigenmode no longer experiences the microcavity resonance (because the chip is antireflection coated), which influences the lasing wavelength, making it possible to achieve a wide tuning range than alternative cavities. In this way, the effect of microcavity resonance is eliminated. In another embodiment, the effect of the microcavity is completely eliminated.

The birefringent filter 18 is inserted in the V-shaped cavity at the Brewster angle to tune the modal gain spectrum of the VECSEL chip 12 to achieve wide tunablility. By “unfolding” the V-shaped cavity about the DBR mirror 28, the VECSEL chip acts as a tilted intracavity etalon within a linear cavity. However, in order to maintain the antinodes of the standing wave in the VECSEL chip 12 at the quantum wells 22, the cavity angle between the two arms of the cavity is kept smaller than 45°.

To eliminate the etalon resonance and walk-off losses in the etalon, a low-reflectivity LR coating 32 may be applied on the surface of the VECSEL chip 12. In a round trip, the capacity mode passes through the active region four times in the V-shaped cavity and two times in the linear cavity. Thus the V-shaped cavity, in which the VECSEL chip 12 serves as a folding mirror, provides higher round-trip gain for a given carrier density and temperature than the other cavities, in which the VECSEL chip works as an end mirror. This higher round-trip gain not only compensates walk-off losses and surface scattering loss, but also enlarges the tunability of the VECSEL structure.

To achieve the tuning, the BF 18 is inserted in one arm of the V-shaped cavity at the Brewster's angle. The BF 18 may be inserted at any position along the laser beam 22 in the cavity. The BF 18 with this special orientation is equivalent to a wave plate sandwiched by two parallel polarizers. The transmission of the BF 18 is given by T=cos²(Δφ/2), where Δφ=2π[nₑ(θ)−nₒ]Lₑ/λ, nₒ and nₑ(θ) are refractive indices for ordinary and extraordinary rays, respectively, λ is vacuum wavelength and Lₑ is the plate thickness along the beam direction within the plate. At 2π[nₑ(θ)−nₒ]Lₑ/λ=2 mπ with m=integer, the transmission of the BF is equal to I, and the laser signal beam at the wavelength λ in the cavity suffers no loss passing through the plate. Rotating the BF 18 about its surface normal changes nₑ, thus tuning the wavelength to the maximum transmission of the filter (T=1). The BF 18 is configured to be rotated about its surface normal by a driving mechanism, not shown in FIG. 1.

Since the cavity mode no longer experiences the microcavity, by rotating the BF, the tuning across the modal gain spectrum can be achieved (proportional to Γᵣ(λ)g(λ)), where Γᵣ(λ) is the relative confinement factor and g(λ) is quantum well gain spectrum, which is a large continuous wavelength tuning range.

In another embodiment of the present invention, the processed VECSEL chip 12 is mounted on the temperature control unit 14 for temperature control. If a fiber coupled multimode 808 nm diode laser pump source is used to pump the VECSEL chip 12, a 500 μm diameter pump spot is focused on the VECSEL chip 12. It is noted that the area of the active region of the VECSEL chip of this embodiment is a few hundred micrometers, which is much larger than the active region in a conventional VECSEL chip (approximately 10 micrometers). In the V-shaped cavity, the distance between the high-reflectivity (R>99.9% at signal wavelength) flat mirror 16 and the VECSEL chip 12 is around 5 cm and the distance between the VECSEL chip 12 and the output coupler 20 (R=92% at signal wavelength, 30 cm radius of curvature) is about 17.5 cm.

The size of a TEM₀₀ mode on the VECSEL chip 12 is about 430 μm in diameter, matching the pump spot size of 500 μm diameter. The cavity angle between the two arms of the V-shaped cavity is about 8.5°, resulting in the refraction angle in the semiconductor to be less than 1.4°. Such a small refraction angle does not significantly change the relative confinement factor. The birefringent filter BF 18 (1 mm thick quartz plate or other equivalent materials) is inserted between the VESCEL chip 12 and the output coupler 20 at the Brewster angle to tune the wavelength of the VECSEL chip 12. The dimensions among the elements of the VECSEL structure of this embodiment are exemplary and not intended to limit the present invention.

FIG. 6 shows the VECSEL TEM₀₀ output power at 10° C. as a function of net pump power for two cases: V-shaped cavity (VC) and V-shaped cavity with birefringent filter (VCBF). Before the BF is inserted in the cavity, the slope efficiency is 0.39. After the BF is introduced in the cavity at the Brewster angle, the linearly polarized VECSEL is tuned to achieve the maximum TEM₀₀ output at each pump level. In this case the laser threshold slightly increases and the slope efficiency decreases by 2% since a small amount of loss is inevitably introduced into the cavity by the BF.

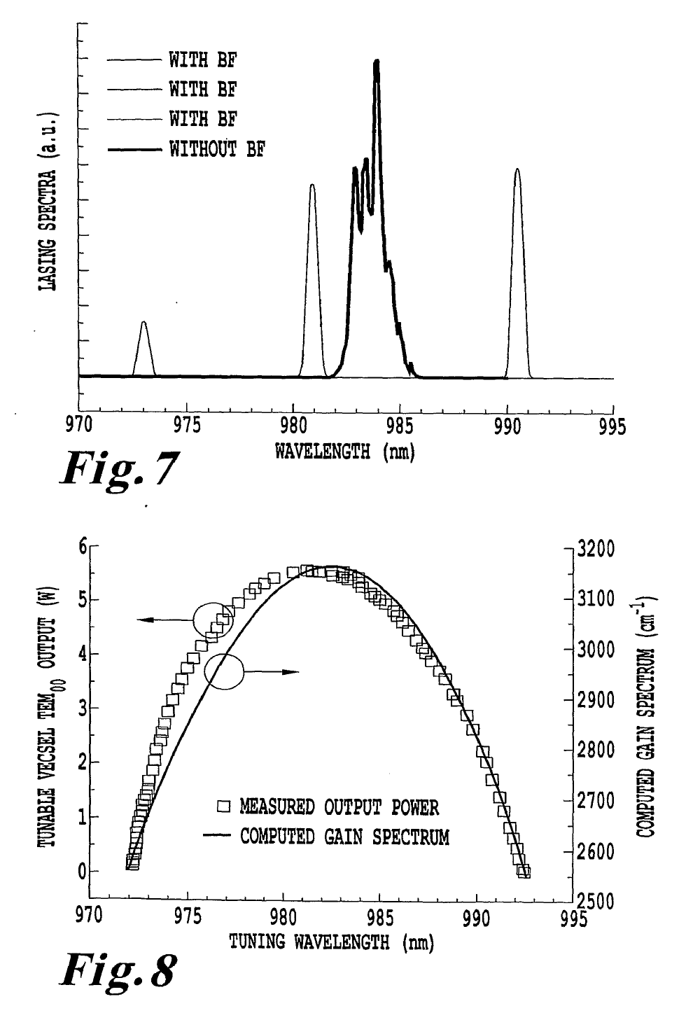

FIG. 7 shows a comparison of the several tuned laser spectra (with BF) and untuned lasing spectrum (without BF) in the V-shaped cavity. The untuned lasing wavelength is located at the peak wavelength of the modal gain spectrum. The cavity mode no longer experiences the effect of microcavity resonance, and the modal gain drops slightly (less than 20% of peak value) in a range of 15 to 20 nm around the peak wavelength of the modal gain spectrum (see FIG. 8). Therefore, the tuned laser wavelength is within this range and is determined by the wavelength at which the maximum transmission of the BF occurs. The tuned lasing spectra achieved with the BF are more uniform and narrow than those achieved without the BF present in the cavity. This is due to the longitudinal mode discrimination afforded by the BF, and the lack of a competing spectral filtering due to the microcavity resonance.

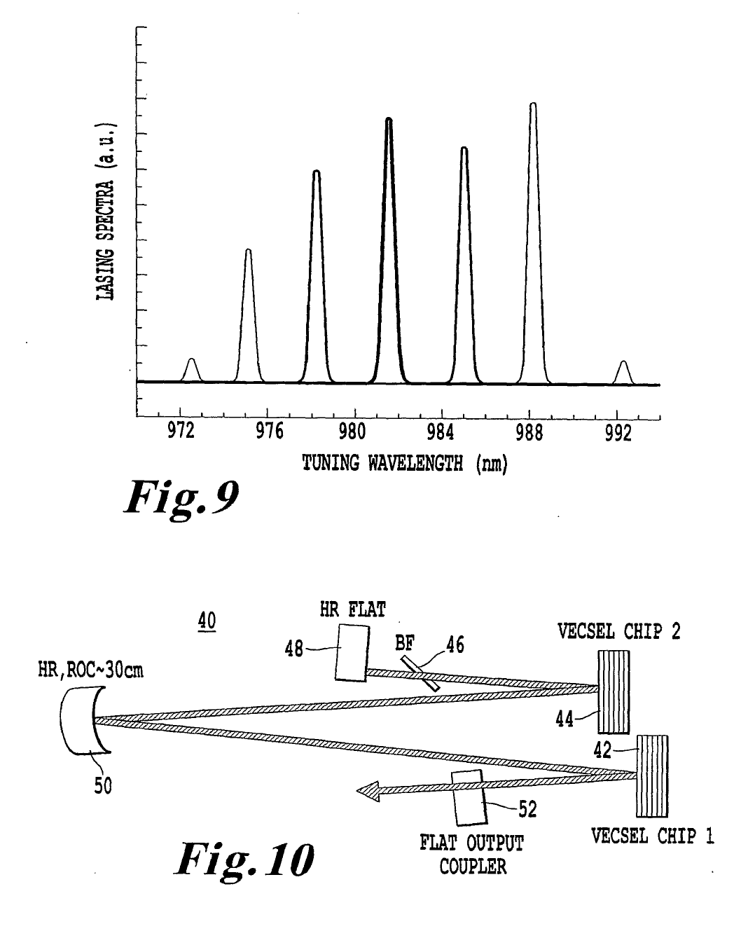

The tunability of the VECSEL with the V-shaped cavity and birefringent filter is shown in FIG. 8. In the graphic, the pump power (24 W) and the temperature of the temperature control unit (10° C.) are fixed. Multiwatt continuous wave linearly polarized TEM₀₀ output with 20 nm tuning range is produced. The tuning range is affected and defined by the bandwidth of the gain spectrum. FIG. 9 shows the lasing spectra of the VECSEL structure of FIG. 1 at several points along the tuning range. Within a 20 nm wavelength tunable range, the envelope of the lasing spectra can be continuously tuned with a narrow linewidth.

Thus, a tunable high-power high-brightness linearly polarized VECSEL with the V-shaped cavity and the birefringent filter can output a multiwaft high-power continuous wave linearly polarized TEM₀₀ with a 20 nm tuning range and narrow linewidth. This effective VECSEL structure achieves a tunability as large as 30 nm and can be generalized to any laser using resonant periodic gain structure.

In another embodiment, a multi-chip VECSEL is used as an efficient coherent power scaling scheme. Multi-chip VECSELs distribute the waste heat on each chip such that more pump power can be launched into the VECSEL chips before the laser reaches its thermal rollover. A two-chip VECSEL with over 19 W output power is shown in FIG. 10. Plural chip VECSEL structures are also possible. Since the gain spectrum of the multi-chip VECSEL is a superposition of the gain spectrum of each chip, a multi-chip VECSEL achieves a higher and broader gain spectrum than a single chip VECSEL does, resulting in a larger tunability with high output power.

Because the quantum well gain spectrum is sensitive to its structure, carrier density and temperature, multi-chip VECSEL provides a flexibility to control its modal gain spectrum by changing the pump or temperature on each chip, manipulating the tuning curve (output power vs. wavelength) of the laser such that the laser provides a larger tuning range and less variation of output power with wavelength.

FIG. 10 shows a tunable two-chip VECSEL structure 40 with two VECSEL chips 42 and 44 arranged in a W-shaped cavity and having a birefringent filter BF 46. The arrangement shown in FIG. 10 may achieve a multi-watts high-brightness linearly polarized output with a tuning range about 33 nm, higher than for the case of the single VECSEL chip.

In this embodiment, the two VECSEL chips are designed for emission around 975 nm and grown by metal-organic vapor phase epitaxy (MOVPE) on an undoped GaAs substrate. However, two or more VECSEL chips having any wavelength emission may be used. The active regions of the VECSEL chip 42 and VECSEL chip 44 may include 14 and 10 InGaAs compressive strained quantum wells, respectively. Each quantum well may be 8 nm thick and surrounded by GaAsP strain compensation layers and AlGaAs pump-absorbing barriers. The thickness and composition of the layers are such that each quantum well is positioned at an antinode of the standing wave to provide RPG. Due to the growth variation, the lasing wavelength of VECSEL chip 42 and chip 44 (at the laser threshold and 0° C.) are around 964 nm and 968 nm, respectively.

A high reflectivity (R>99.9%) DBR stack made of 25-pairs of AlGaAs/AlAs is grown on top of the active region. In addition to the RPG active region and DBR stack, there is a high aluminum concentration AlGaAs etch-stop layer between the active region and the substrate to facilitate selective chemical substrate removal, similar to the VECSEL chip of FIG. 1. The epitaxial side of the VECSEL wafer is mounted on chemical vapor deposition (CVD) diamond by indium solder. After the removal of the GaAs substrate and etch-stop layer, a single layer Si₃N₄ (n=1.78 at 980 nm) quarter wave LR coating (for 975-nm signal) is deposited on the surface of the VECSEL chip to achieve a reflectivity of less than 1% at the signal wavelength.

A W-shaped cavity as illustrated in FIG. 10 is obtained by using the flat mirror 48, the BF 46, the two VECSEL chips 42 and 44, a concave mirror 50, and an output coupler 52. Although the VECSEL chip 12 disclosed in the V-shaped cavity may be used in this embodiment, the two-chip VECSELs 42 and 44 have a structure different from the VECSEL chip 12. In the cavity, the radius of curvature (ROC) of the concaved spherical folding mirror is 30 cm and the full folding angle of the cavity is about 15°. As discussed above, the BF 46 may be replaced by other wavelength tuning components.

A distance between the concaved mirror and the VECSEL chip 42 and chip 44 are around 24 cm and 21 cm, respectively. The flat output coupler 52 is 4.5 cm away from the VECSEL chip 42, and the flat high reflecting (HR) mirror 48 is 7 cm from the chip 44. A 2-mm thick quartz plate is inserted between the flat HR mirror 48 and the chip 44 at Brewster's angle serving as the BF 46. The BF 46 has a low loss at the tuned wavelength, and introduces the longitudinal mode discrimination to narrow the lasing spectra. Other materials, known by the one of ordinary skill in the art to be equivalent to the disclosed materials of the elements of the cavity disclosed above may be used. The dimensions and characteristics provided above are for exemplary purposes and not intended to limit the present invention.

This cavity configuration defines a TEM₀₀ mode size on the VECSEL chip 42 of approximately 350 μm diameter (tangential) and approximately 360 μm diameter (sagittal); and on the VECSEL chip 44 approximately of 420 μm diameter (tangential and sagittal). Two 808-nm fiber coupled pump lasers (not shown) are focused on VECSEL chip 42 with a pump spot size of 410 μm (in diameter) and 480 μm (in diameter) on chip 44, respectively. Both pump spot sizes match the fundamental mode sizes on the chips to force the lasers to operate in the TEM₀₀ mode.

The concaved spherical mirror 50 introduces a difference between the tangential and sagittal focal lengths, making the laser beam asymmetric (elliptical). To decrease this asymmetry, the folding angle at the concaved spherical mirror may be made small. To take advantage of the RPG, the folding angle on both chips may be made small.

For a given carrier density, the quantum well gain peak shifts to longer wavelengths with temperature at a rate of approximately 0.3 nm/K. Since the lasing wavelength of VECSEL chip 42 and chip 44 (at the laser threshold and 0° C.) are around 964 nm and 968 nm, respectively, the chip 42 may be cooled and the chip 44 heated to broaden the gain spectrum of the two-chip VECSEL for a larger tunability.

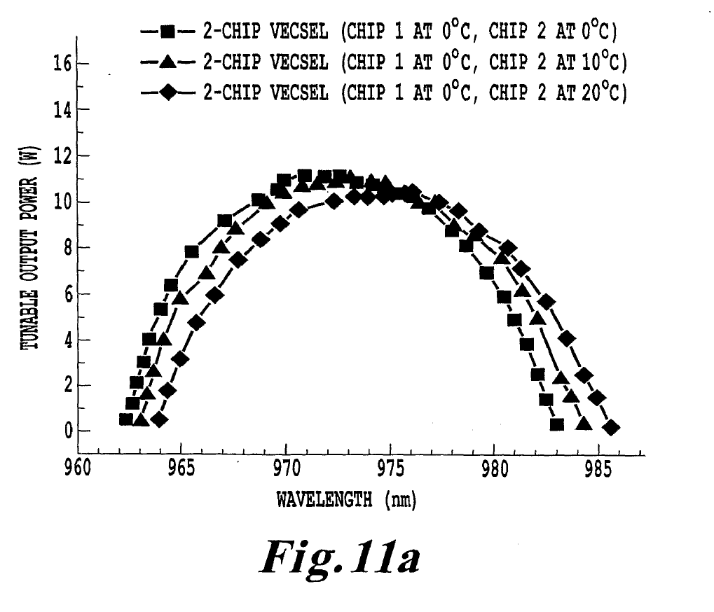

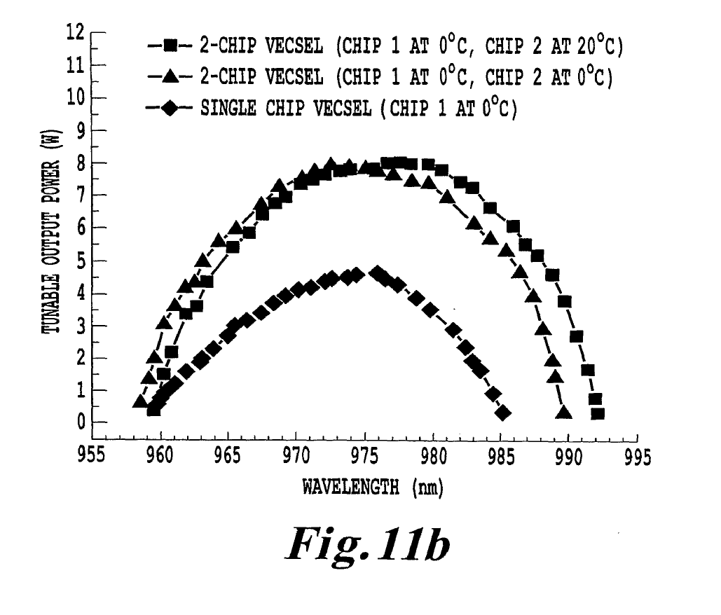

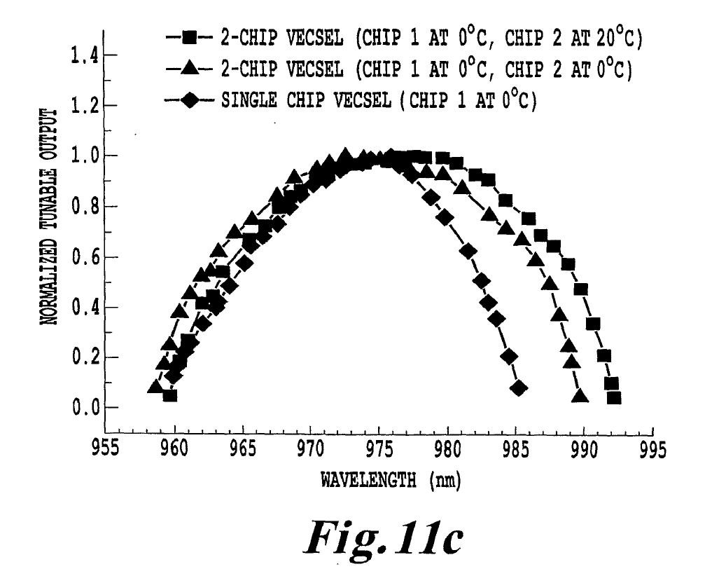

FIG. 11a shows the laser tuning performance when the output coupler (1) with a reflectance of 90% to 92% is used. The laser tuning is performed with the chip 42 kept at 0° C., and the chip 44 kept at 0° C., 10° C., and 20° C., respectively. A peak output power over 10 W and a wavelength tuning range over 21 nm are achieved by the structure shown in FIG. 10. The tuning curve and peak wavelength globally shift to longer wavelengths and the peak power slightly decreases when the temperature on chip 44 increases. This is due to the red-shift of the quantum well gain and gain peak drop with the increase of the temperature. Compared to a single chip tunable VECSEL, the top of tuning curve is much flatter, indicating the change of the shape of the gain spectra with the temperature on chip 44.

FIG. 11c shows the laser tuning performance when the output coupler (2) with a reflectance of 96% to 97.5% is used. Using an output coupler with a higher reflectance, the cavity losses are decreased, resulting in a larger tunability. However, the output power is reduced. Under similar conditions (chip 42 at 0° C., and chip 44 at ° C. and 20° C., respectively), the peak output power over 8 W and the wavelength tuning range over 33 nm are achieved. With the increase of the temperature on chip 44, the tunability increases slightly and the tuning curve globally red-shifts.

To compare the tuning properties of two-chip tunable VECSEL and single chip tunable VECSEL with a V-shaped cavity and BF (the same BF used in the above two-chip tunable VECSEL), the tuning curve of each structure is shown in FIG. 11c. The chip 42 is on the temperature control unit with a temperature of 0° C., and the pump density is the same as that on chip 42 in two-chip tunable VECSEL (25.6 W on 480 μm (diameter) pump spot). The output coupler (2) is used and the cavity is used for TEM₀₀ mode operation. The tuning curve in FIG. 11b shows 25-nm tuning range and 4.7-W peak output power. To make the comparison simpler, each tuning curve in FIG. 11b is normalized to its own peak power. FIG. 11c show their normalized tuning curves. The larger tuning ranges and the improved flatness on the top of the tuning curves indicate that the two-chip tunable VECSEL has less tunable output power variation with wavelength than the single chip VECSEL. The difference between them reflects the contribution from chip 44 in the two-chip tunable VECSEL.

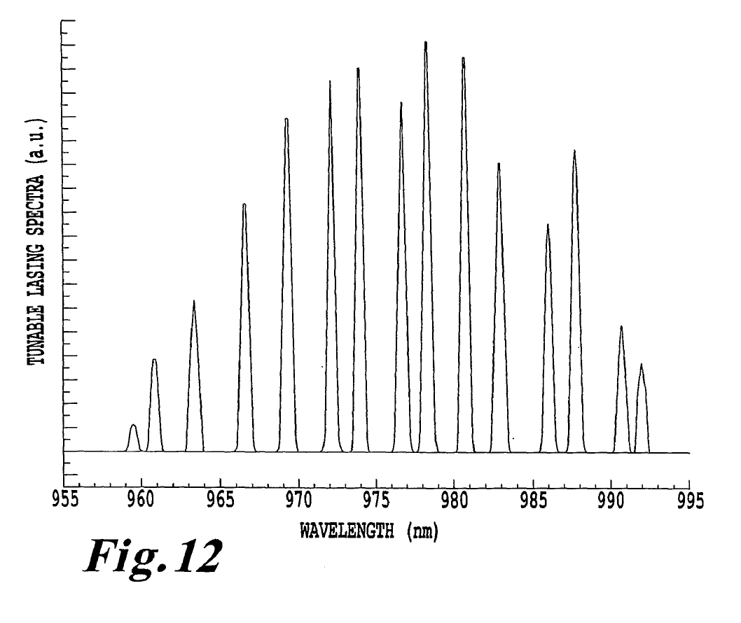

FIG. 12 shows tuning spectra along the tuning range. The variation of the strength of spectra is due to a fiber coupling to a multimode fiber for the purpose of measurement, not the intensity of the output beam. The linewidth is around 1 nm. The beam quality is measured by a real-time beam profiler BeamMap (DataRay Inc.). Since the pump size matches the fundamental mode size according to an embodiment of the present invention, the beam quality factor (M² factor) is closed to 1.7 at peak output power.

Thus, according to an embodiment of the present invention, a multi-watts high-brightness linearly polarized tunable two-chip VECSEL with a W-shaped cavity and a BF is achieved. The modal gain spectrum of the two-chip VECSEL is the superposition of two gain spectra from different VECSEL chips, making the gain spectra higher and broader. This configuration provides a flexibility to shape the gain spectrum of the laser by controlling the pump/temperature on each chip, which makes easier to manipulate the tuning curve (output power vs. wavelength) of the laser. The two-chip VECSEL shows less output power variation and larger tunability than a single chip VECSEL. The multi-watts high-brightness linearly polarized output has a tuning range of 33 nm.

According to another embodiment of the present invention, a tunable watt-level VECSEL structure covers a wider wavelength range (from the near ultraviolet to the midinfrared) than conventional diode-pumped solid-state lasers. This VECSEL structure produces a blue-green laser beam, which is desirable for many fields.

The frequency conversion in a nonlinear crystal is used to achieve the blue-green laser beam. Intracavity second-harmonic generation (SHG) is an efficient way to obtain visible VECSELs. Combining intracavity frequency doubling with the multiwatt tunable VECSEL operating around 976 nm (discussed above with reference to FIGS. 2 and 4) provide wavelength-tunable laser operation around 488 nm by rotating the non-linear crystal. With a few nanometers wavelength tuning range, this tunable blue-green laser provides the desirable wavelength range for bio-medical fluorochromes excitation, flow cytometry, and some spectroscopic applications.

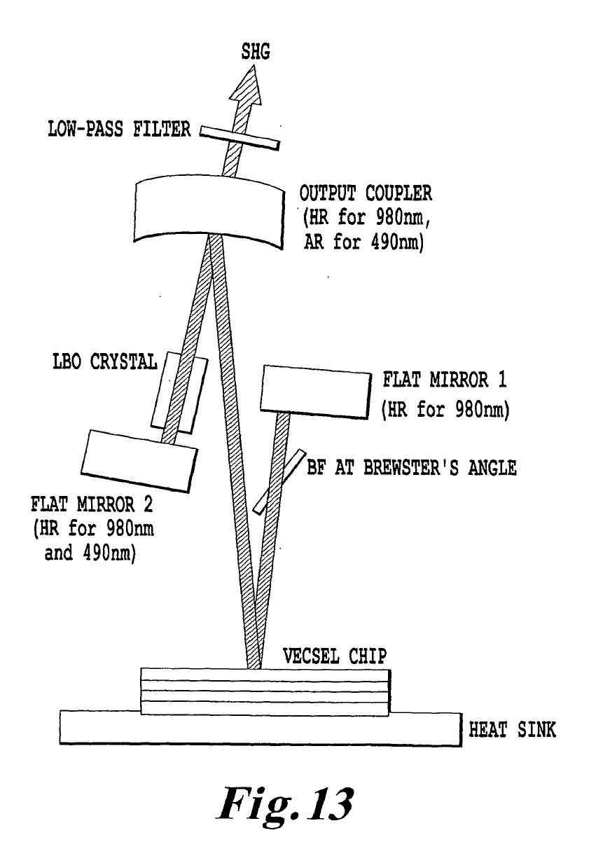

In one embodiment, FIG. 13 shows a tunable watt-level blue-green linearly polarized VECSEL operating around 488 nm with a 5 nm tuning range. The VECSEL structure of FIG. 13, designed for emission around 975 nm, is grown by metal-organic vapor phase epitaxy (MOVPE) on an undoped GaAs substrate. The active region may include 14 InGaAs compressive strained quantum wells. Each quantum well may be 8 nm thick and surrounded by (approximately 31 nm thick) GaAsP strain compensation layers and Al-GaAs pump-absorbing barriers. The thickness and composition of the layers are such that each quantum well is positioned at an antinode of the standing wave to provide RPG. A high reflectivity (R>99.9%) DBR stack made of 25 pairs of Al_{0.2}Ga_{0.8}As/AlAs is grown on the top of the active region. In addition to the RPG active region and DBR stack, there is a high aluminum concentration AlGaAs etch-stop layer between the active region and the substrate to facilitate selective chemical substrate removal.

The epitaxial side of the VECSEL wafer is mounted on chemical vapor deposition (CVD) diamond by indium solder. After the removal of the GaAs substrate and etch-stop layer, a single layer Si₃N₄ (n=1.78 at 980 nm) quarter wave low-reflection coating (for 975 nm signal) is deposited on the surface of VECSEL chip to achieve a reflectivity of less than 1% at the signal wavelength. Other VECSEL chips are possible as will be recognized by one of ordinary skill in the art. The specific materials and dimensions disclosed in this embodiment are for exemplary purposes and not for limiting the invention.

A Z-shaped cavity as illustrated in FIG. 13 is used for tunable intracavity SHG. The cavity includes a VECSEL chip 60, which may be provided on a temperature control unit 62, a flat mirror 64, a birefringent filter BF 66, an output coupler 68, a non-linear crystal as for example a lithium triborate LBO crystal 70 (or equivalents of this non-linear crystal as beta barium borate, potassium titanium oxide phosphate, potassium dihydrogen phosphate, and potassium dideuterium phosphate or other non-linear crystals as will be appreciated by one of ordinary skill in the art), and another flat mirror 72. The VECSEL chip 60 is coated with an antireflection (AR) layer, and serves as an active folding mirror to provide high round trip gain and a large tunability for the fundamental beam.

In order to take advantage of the RPG structure, the folding angle at the VECSEL chip 60 is kept small. By “unfolding” the Z-shaped cavity about the VECSEL DBR mirror, the VECSEL active region acts as a tilted intracavity etalon To weaken the resonance of this tilted etalon and eliminate its walk-off losses, a low reflectivity coating may be applied on the surface of the VECSEL chip 60.

The birefringent filter BF 66 is inserted in the cavity at Brewster's angle. For a fundamental signal, the functions of the BF 66 are threefold: a low-loss wavelength tuning component, a Brewster window to select polarization, and a filter introducing longitudinal mode discrimination. The linear polarization and narrow linewidth of the fundamental beam are used for the SHG phase-matching condition. In this cavity there exist two beam waists on flat mirror 64 and on flat mirror 72, respectively. Since the beam waist at flat mirror 72 is smaller than that at flat mirror 64, the lithium triborate LBO crystal 70 is inserted close to the flat mirror 72 such that the highest fundamental beam intensity is in the crystal.

To build a high Q cavity for high-power circulating fundamental beam, all of cavity mirrors may be highly reflective around 976 nm. Since the VECSEL chip 60 is highly absorbing the SHG signal, the output coupler 68 may be transparent for the SHG signal around 488 nm. The tilted concaved spherical output coupler 68 provides a difference between the tangential and sagittal focal lengths, making the fundamental beam and SHG beam asymmetric. To neglect this asymmetry, the folding angle at the output coupler 68 is kept small. A low-pass filter 74 is used after the output coupler 68 to select a desirable wavelength of the output.

The processed VECSEL chip 60, (which may be one of the VECSEL chips discussed in the previous embodiments) is mounted on the temperature control unit 62 for temperature control. In this embodiment, the coating of the output coupler 68 and the flat mirror 72 are not optimal. For example, the reflectance of the output coupler is only approximately 99% at 976 nm and approximately 30% at 488 nm, lowering the cavity Q factor for 976 nm lasing wavelength and reflecting part of the SHG to the VECSEL chip. The reflectance of the flat mirror 72 is 99.9% at 976 nm and 80% at 488 nm, leaking the SHG.

The lasing of the structure of the present embodiment is produced by using an 808 nm diode laser pump source lens coupled to the chip, resulting in 600 μm diameter pump spot. A length of each segment of the Z-shaped cavity is about 7.5 cm between the flat mirror 64 and the VECSEL chip 60, 10.5 cm between the chip 60 and the output coupler 68 (7.5 cm radius of curvature), and 4.5 cm between the output coupler 68 and the flat mirror 72.

The cavity configuration of FIG. 13 produces the smaller fundamental beam waist (only 40 μm) at the flat mirror 72, so that the highest fundamental beam intensity in the cavity appears in the LBO crystal 70 to maximize the intracavity SHG. The size of the TEM₀₀ mode on the VECSEL chip is about 540 μm diameter, substantially matching the pump spot size. The folding angle at VECSEL chip is about 8°, resulting in the refraction angle in the semiconductor to be less than 1.4°. Such a small refraction angle allows antinodes of the standing wave to overlap each quantum well in the VECSEL active region.

The other folding angle on the output coupler 68 is about 10°, making the difference of the tangential and sagittal focal lengths negligible. The BF 66 (1 mm thick quartz plate) is inserted between the chip 60 and the flat mirror 64 at Brewster's angle to select the fundamental beam wavelength, to narrow its linewidths and to fix its polarization. The low-pass filter 74 is used to block the fundamental beam output for measuring the SHG output power.

The LBO crystal 70 is a nonlinear optical crystal used for intracavity SHG due to its broad transparency range, relative large effective SHG coefficient, high damage threshold, and small walk-off. Since the BF 66 is placed in the cavity at Brewster's angle, a type-I phase-matched scheme is chosen as discussed next. To make the alignment easier and keep a high effective SHG coefficient, for the 980 nm fundamental laser beam of the chip and 490 nm SHG, the phase-matching conditions include an angle θ (between the fundamental beam propagation direction and the Z axis of the crystal) which is 90° and an angle φ (between the fundamental beam propagation direction and the X axis of the crystal) which is 170. The fundamental beam and the SHG propagation are confined in the XY plane of the LBO crystal 70. The polarization of the fundamental beam is parallel to the Z axis of the LBO crystal, and the polarization of the SHG is orthogonal to the Z axis. A piece of the LBO crystal (3×3×10 mm³) is cut to satisfy the type-I angle phase-matching condition and both facets are AR coated for the fundamental and SHG wavelengths.

When the wavelength of the fundamental beam is tuned in the range of 980±110 nm, the phase-matching condition is met by tilting φ angle±0.7° (i.e., θ=90° and φ=17±0.70). However, the tilting angle will not cause any additional cavity alignment for the fundamental signal because the fundamental beam is still perpendicular to the flat mirror 72. The LBO crystal 70 and the flat mirror 72 are separately mounted on the different translation stages with tilt. In other words, the LBO crystal 70 and the flat mirror 72 are rotable mounted. Their positions are adjusted to achieve a maximum intracavity SHG.

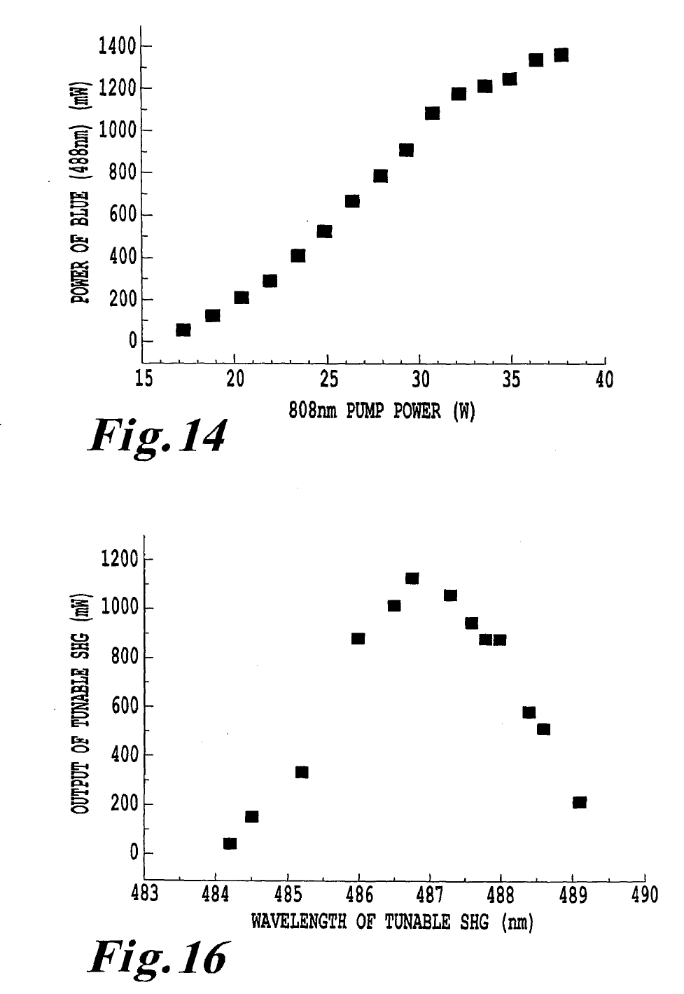

FIG. 14 shows the total continuous wave 488 nm blue-green power generated by the LBO crystal as a function of a 808 nm net pump power. In this embodiment, the wavelength of the fundamental beam is locked at 976 nm by the BF 66. Over 1.3 W intracavity SHG is generated by the LBO crystal. The reflectance of the output coupler 68 at 976 nm is 99%. 1.06 W output at 976 nm is produced when blue output is more than 1.3 W.

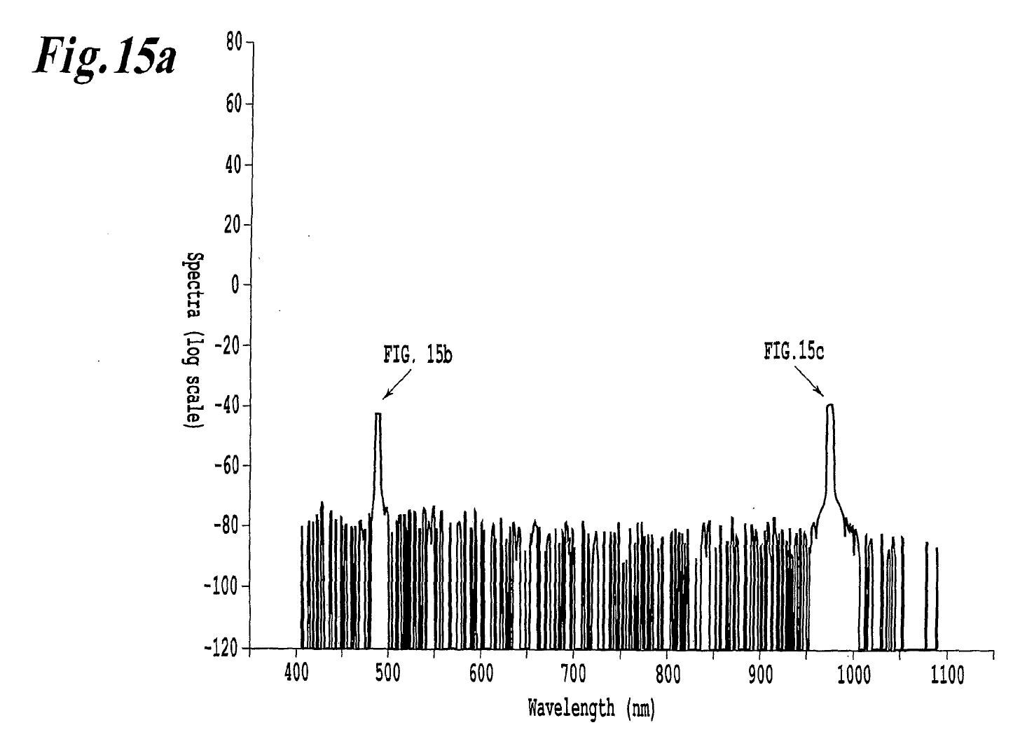

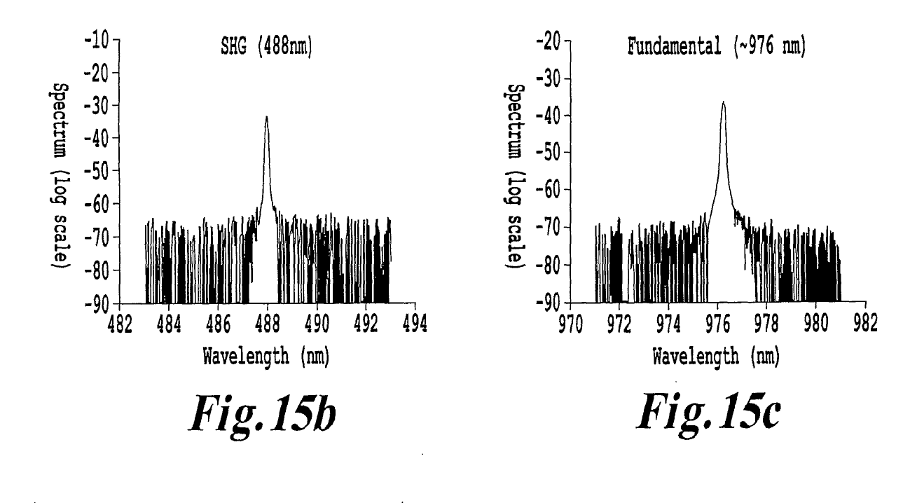

FIGS. 15a-c show the spectra of the fundamental beam around 976 nm and SHG at 488 nm when the output of the intracavity is over 1 W. The shape of spectrum of fundamental beam is similar to that of the SHG. The full width at half maximum (FWHM) of the fundamental signal is around 0.4 nm and the total optical length of the cavity is about 24 cm, indicating that there are more than 200 longitudinal modes in the spectral envelope. This multimode operation prevents severe output fluctuation caused by the nonlinear interaction of the longitudinal modes, namely, the “green problem” of conventional intracavity SHG.

For a given temperature and carrier density, the tunability of the fundamental beam is determined by the cavity loss. Without the LBO in the cavity, the tuning range of the fundamental lasing signal is about 20 nm. With the LBO crystal in the cavity, the tuning range of the fundamental signal decreases to about 10 nm due to the losses introduced by the intracavity SHG, the roughness of the two LBO crystal facets (measured flatness and wave front distortion on both facets: λ/8 at 633 nm), and the absorption of the LBO crystal. The tunability of the blue-green VECSEL with the Z-shaped cavity and the BF is shown in FIG. 16. The graphic shown in FIG. 16 is obtained for a pump power of 35 W and the temperature control unit temperature of 10° C. being fixed. Linearly polarized tunable blue-green VECSEL with 5 nm tuning range is shown.

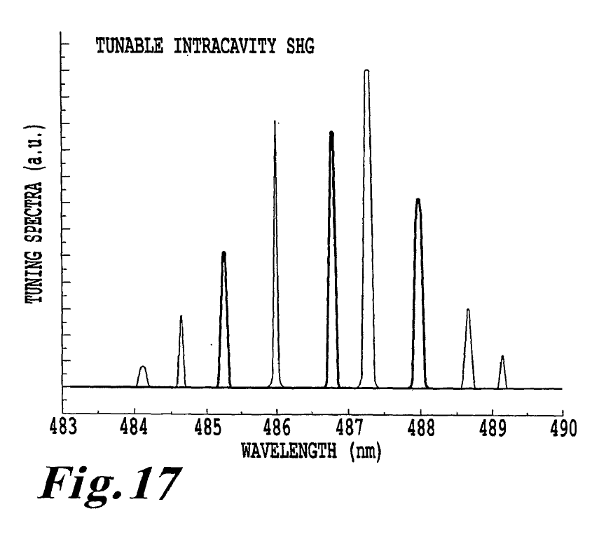

FIG. 17 shows the lasing spectra of the blue-green VECSEL at several points along the tuning range. Within a 5 nm wavelength tuning range the envelope of the SHG spectra is continuously tuned with a narrow linewidth.

Thus, according to the present embodiment, a compact tunable watt-level linearly polarized blue-green VECSEL with a Z-shaped cavity and a birefringent filter by intracavity SHG using the LBO crystal is achieved. Although the coating of the cavity mirrors is not optimized, over 1.3 W continuous wave SHG at 488 nm is generated and a 5 nm tuning range around 488 nm with a narrow linewidth is obtained near room temperature. This tunable blue-green VECSEL provides a desirable wavelength range for biotechnology and is useful for spectroscopic applications.

Multiwatt blue-green laser operation with a wider tunability could be improved if the cavity is optimized, the LBO window flatness (peak to valley height) reaches λ/20 (˜50 nm) and the crystal is mounted on a thermoelectric cooler for temperature control.

Numerous modifications and variations of the present invention are possible in light of the above teachings. It is therefore to be understood that within the scope of the appended claims, the invention may be practiced otherwise than as specifically described herein.

What is claimed is:

1. A laser apparatus comprising:
a first surface-emitting laser device having an active region including at least one group of two or more quantum wells configured to generate photons and having an internal mirror configured to reflect the generated photons; and
first and second opposing end cavity mirrors optically coupled to each other via the internal mirror of the first surface-emitting laser device and arranged to reflect the photons generated by the first surface-emitting laser device back to the first surface-emitting laser device to form a standing wave having a single antinode coincident with said at least one group of two or more quantum wells.

2. The laser apparatus of claim 1, further comprising:
a strain compensating layer separating two quantum wells of the at least one group and arranged coincident with the single antinode of the standing wave.

3. The laser apparatus of claim 2, wherein each quantum well of the at least one group comprises an InₓGa₁₋ₓAs layer with 0.0<x<1.0.

4. The laser apparatus of claim 2, wherein the strain compensating layer comprises a GaAsₓP₁₋ₓ layer having 0.0<x<1.0.

5. The laser apparatus of claim 1, wherein the active region comprises between 7 and 18 groups of quantum wells.

6. The laser apparatus of claim 1, further comprising:
a wavelength tuning device optically coupled to the first surface-emitting laser device and having an incident surface upon which the standing wave is incident, said wavelength tuning device configured to rotate about an axis normal to the incident surface, and to generate different wavelengths for different rotations of the wavelength tuning device.

7. The laser apparatus of claim 6, wherein the wavelength tuning device includes one of a birefringent filter, a Fabry-Perot etalon, a Pockels effect based device, a Kerr effect-based device, and a liquid crystal.

8. The laser apparatus of claim 6, wherein the wavelength tuning device includes a birefringent filter having an incident surface arranged at the Brewster's angle relative to the standing wave.

9. The laser apparatus of claim 1, further comprising:
a wavelength tuning device optically provided in a first optical path defined by the first surface-emitting laser device and the first end cavity mirror, or in a second optical path defined by the first surface-emitting laser device and the second end cavity mirror, the first and second optical paths forming a V-shaped external optical cavity.

10. The laser apparatus of claim 1, further comprising:
a temperature control device provided on the first surface-emitting laser device and configured to remove heat from the first surface-emitting laser device.

11. The laser apparatus of claim 1, further comprising:
a second surface-emitting laser device optically coupled to the first surface-emitting laser device; and
an intermediary mirror optically coupled to the first and second surface-emitting laser devices and configured to reflect the standing wave from the first surface-emitting laser device to the second surface-emitting laser device and vice versa,
wherein one of the first and second end cavity mirrors reflects the standing wave back to the first surface-emitting laser device through the second surface-emitting laser device.

12. The laser apparatus of claim 11, further comprising:
a wavelength tuning device optically coupled to a first optical path defined by the first surface-emitting laser device and the first end cavity mirror, or to a second optical path defined by the first surface-emitting laser device and the intermediate mirror, or to a third optical path defined by the intermediate mirror and the second surface-emitting laser device, or to a fourth optical path defined by the second surface-emitting laser device and the second end cavity mirror, the first to fourth optical paths forming a W-shaped external optical cavity.

13. The laser apparatus of claim 12, wherein the wavelength tuning device includes one of a birefringent filter, a Fabry-Perot etalon, a Pockels effect based device, a Kerr effect-based device, and a liquid crystal.

14. The laser apparatus of claim 11, further comprising:
a first temperature control device thermally coupled to the first surface-emitting laser device and configured to remove heat from the first surface-emitting laser device; and
a second temperature control device thermally coupled to the second surface-emitting laser device and configured to remove heat from the second surface-emitting laser device independently of the first temperature control device.

15. The laser apparatus of claim 1, further comprising:
a nonlinear crystal optically disposed between the first surface-emitting laser device and one of the first and second end cavity mirrors, and configured to nonlinearly convert a wavelength of the standing wave to a different wavelength.

16. The laser apparatus of claim 15, further comprising:
an intermediary mirror optically coupled to one of the first and the second end cavity mirrors; and
a wavelength tuning device optically coupled to a first optical path defined by the first surface-emitting laser device and the first end cavity mirror, or to a second optical path defined by the first surface-emitting laser device and the second end cavity mirror, or to a third optical path defined by the one of the first and second end cavity mirrors and the intermediate mirror, the first to third optical paths forming a Z-shaped external optical cavity.

17. The laser apparatus of claim 15, wherein the nonlinear crystal includes one of a lithium triborate, beta barium borate, potassium titanium oxide phosphate, potassium dihydrogen phosphate, and potassium dideuterium phosphate crystal.

18. A method for tuning a laser beam, comprising:
emitting from a first surface-emitting laser device having an active region that includes at least one group of two or more quantum wells an electromagnetic wave in a first optical path towards a first end cavity mirror;
reflecting the emitted electromagnetic wave from the first end cavity mirror back to an internal mirror of the first surface-emitting laser device for amplification by the first surface-emitting laser device and further emission of the amplified electromagnetic wave in a second optical path to a second end cavity mirror opposing the first end cavity mirror via the first and second optical paths; and
reflecting the amplified electromagnetic wave from the second end cavity mirror back to the internal mirror of the first surface-emitting device for further amplification of the electromagnetic wave so that a standing wave having a single antinode located at the at least one group of two or more quantum wells in the active region is formed.

19. The method of claim 18, further comprising:
tuning the amplified electromagnetic wave with a wavelength tuning device optically coupled to the first surface-emitting laser device.
